(19) United States
(12) Patent Application Publication
(10) Pub. No.: US 2014/0370275 A1
(43) Pub. Date: Dec. 18, 2014

(54) SUBSTRATE WITH TRANSPARENT ELECTRODE AND METHOD FOR MANUFACTURING SAME

(71) Applicant: KANEKA CORPORATION, Osaka-shi, Osaka (JP)

(72) Inventors: Takashi Kuchiyama, Settsu-shi (JP); Hironori Hayakawa, Settsu-shi (JP); Hiroaki Ueda, Otsu-shi (JP); Takahisa Fujimoto, Settsu-shi (JP); Kenji Yamamoto, Settsu-shi (JP)

(73) Assignee: KANEKA CORPORATION, Osaka-shi, Osaka (JP)

(21) Appl. No.: 14/374,876

(22) PCT Filed: Jan. 18, 2013
(86) PCT No.: PCT/JP2013/050923

§ 371 Date: Jul. 25, 2014

(30) Foreign Application Priority Data
Jan. 27, 2012 (JP) 2012-015995

(51) Int. Cl. H05K 1/02; C23C 14/58; C23C 14/34; H05K 1/09

(52) U.S. Cl. CPC H05K 1/0274; H05K 1/092; C23C 14/5806; C23C 14/3407; H05K 2201/0329
USPC 428/336; 204/192.15

(57) ABSTRACT

The present invention relates to a substrate with a transparent electrode, which has a transparent electrode layer on at least one surface of a transparent film base material. The transparent film base material has a transparent dielectric material layer containing an oxide as a main component on a surface at the transparent electrode layer side. In one embodiment of the present invention, the transparent electrode layer is a crystalline transparent electrode layer that has a crystallinity degree of 80% or more. In this embodiment, the crystalline transparent electrode layer has a resistivity of 3.5×10⁻⁴ Ω·cm or less, a thickness of 15 nm to 40 nm, an indium oxide content of 87.5% to 95.5%, and a carrier density of 4×10²⁰/cm³ to 9×10²⁰/cm³, and the substrate with the transparent electrode preferably has a heat shrinkage start temperature of 75° C. to 120° C. as measured by thermomechanical analysis.

### TECHNICAL FIELD

The present invention relates to a substrate with a transparent electrode, in which a transparent electrode layer is formed on a transparent film base material, and a method for manufacturing same.

### BACKGROUND ART

A substrate with a transparent electrode, in which a conductive oxide thin film such as that of an indium-tin composite oxide (ITO) is formed on a transparent base material such as a transparent film or glass, is widely used as a transparent electrode of a display, a light emitting element, a photoelectric conversion element, or the like. As a method for manufacturing such a substrate with a transparent electrode, a method is widely used in which a conductive oxide thin film is formed on a transparent base material by the sputtering method. Preferably, the conductive oxide to be used for the transparent electrode is crystallized from the viewpoints of improving the transmittance and suppressing a change in resistance value.

When a heat-resistant base material such as glass is used as the transparent base material, deposition is performed at a high temperature of, for example, 200° C. or higher to form a crystalline conductive oxide thin film. On the other hand, when a film is used as the transparent base material, the deposition temperature cannot be increased in view of the heat resistance of the base material. Accordingly, an amorphous conductive oxide thin film is formed on the base material at a low temperature, and then heated under an oxygen atmosphere to crystallize the thin film (for example, Patent Document 1).

However, heating for crystallization is required to be performed at a high temperature of about 150° C., and therefore the film base material may undergo a dimensional change and disrupt the design of a device. Further, crystallization requires heating for about 30 minutes to several days. Accordingly, formation of an amorphous conductive oxide thin film on the film base material is performed by the roll-to-roll method, whereas crystallization of a conductive oxide thin film is unfit for the roll-to-roll method, and is generally performed with the film cut into a predetermined size. Thus, necessity of crystallization of a conductive oxide thin film at a high temperature contributes to a reduction in productivity and an increase in costs of a substrate with a transparent electrode using a film base material.

In recent years, on-cell type touch panels have been progressively developed in which a transparent electrode layer for position detection is disposed between a liquid crystal cell and a polarizing plate in a liquid crystal panel. In the on-cell type touch panel, the number of members can be reduced by providing a transparent electrode layer on an optical compensation film (e.g., wide viewing angle film) or a polarizing plate which is required for formation of images on the liquid crystal panel. The optical compensation film, polarizing plate or the like is made to exhibit birefringence and polarization functions by orienting polymers, liquid crystal molecules, or the like, and therefore may lose functions as an optical film due to relaxation of orientation of molecules when heated at a high temperature. Therefore, the transparent electrode layer which requires heating at a high temperature for crystallization is difficult to apply to the on-cell type touch panel.

Furthermore, from the viewpoints of improving the response speed of a capacitance touch panel and improving in-plane uniformity of luminance in organic EL illumination, demand has increased for a substrate with a transparent electrode, which includes a transparent electrode layer having a low resistance. However, it is difficult to obtain a transparent electrode layer having a low resistance with a method in which an amorphous metal oxide thin film is formed, and then crystallized by heating.

### PRIOR ART DOCUMENT

### Patent Document

Patent Document 1: International Publication No. WO 2010/035598

### SUMMARY OF THE INVENTION

### Problems to be Solved by the Invention

In view of the above-mentioned situations, an object of the present invention is to provide a substrate with a transparent electrode and a manufacturing method thereof, wherein the substrate with a transparent electrode includes a transparent electrode layer that can be crystallized at room temperature or by low-temperature heating and that has a low resistance.

### Means for Solving the Problems

The present inventors have conducted intensive studies, and resultantly found that an amorphous transparent electrode layer deposited under a specific condition can be crystallized under the condition of a low temperature such as room temperature, leading to the present invention. That is, the present invention relates to a substrate with a transparent electrode, which has a transparent electrode layer on at least one surface of a transparent film base material, and a method for manufacturing the same.

In the substrate with a transparent electrode according to the present invention, the transparent film base material preferably has a transparent dielectric material layer containing an oxide as a main component on a surface at the transparent electrode layer side. The transparent dielectric material layer is preferably one containing silicon oxide as a main component.

In one embodiment of the present invention, the substrate with a transparent electrode includes a crystalline transparent electrode layer on at least one surface of the transparent film base material. The crystalline transparent electrode layer preferably has a resistivity of 3.5×10⁻⁴ Ω·cm or less, a thickness of 15 nm to 40 nm, a carrier density of 4×10²⁰/cm³ to 9×10²⁰/cm³, and a crystallinity degree of 80% or more. The transparent electrode layer preferably has an indium oxide content of 87.5% to 95.5%, and preferably further contains tin oxide or zinc oxide.

In one embodiment of the present invention, an amorphous transparent electrode layer is formed through the steps of providing a transparent film base material (base material providing step), and forming an amorphous transparent electrode layer on a transparent dielectric material layer of the transparent film base material by a sputtering method (deposition step). After the deposition step, a substrate with a transparent electrode, which includes a crystalline transparent electrode layer on a transparent film base material, is obtained through a crystallization step of crystallizing the amorphous transparent electrode layer.

The amorphous transparent electrode layer preferably has a thickness of 15 nm to 40 nm and a crystallinity degree of less than 80%. The activation energy in crystallization of the amorphous transparent electrode layer is preferably 1.3 eV or less. The substrate with a transparent electrode according to the present invention, which has an amorphous transparent electrode layer on a transparent film base material, preferably has a heat shrinkage start temperature of 75° C. to 120° C.

In the present invention, the activation energy in crystallization of the amorphous transparent electrode layer is low, and therefore a crystalline transparent electrode layer can be obtained in the crystallization step without heating the transparent film base material and the transparent electrode layer to 120° C. or higher. In one embodiment, the crystallization step is performed at ambient temperature and ambient pressure.

As the transparent film base material before being subjected to the deposition step, one that is not subjected to a heat shrinkage reducing treatment and that has a relatively large heat shrinkage amount is suitably used. The transparent film base material before being subjected to the deposition step preferably has a heat shrinkage start temperature of 75° C. to 120° C. as measured by thermomechanical analysis. The transparent film base material before being subjected to the deposition step preferably has a heat shrinkage percentage of 0.4% or more when heated at 150° C. for 30 minutes.

In the deposition step, preferably, deposition is performed by the sputtering method at an oxygen partial pressure of 1×10⁻³ Pa to 5×10⁻³ Pa in a deposition chamber while a carrier gas including an inert gas and an oxygen gas is introduced into the chamber. The substrate temperature in the deposition step is preferably 60° C. or lower. Deposition is performed under the condition of a relatively low oxygen partial pressure, so that an amorphous transparent electrode layer having low activation energy in crystallization as described above can be obtained.

In one embodiment of the present invention, the substrate with a transparent electrode is a continuous roll with a long sheet wound in a roll shape. For example, when the deposition step is performed using a roll-to-roll sputtering apparatus, a continuous roll of a substrate with a transparent electrode, which includes an amorphous transparent electrode layer, is obtained. As described above, in the present invention, the crystallization step can be performed in an environment at a relatively low temperature (e.g., ambient temperature and ambient pressure), and therefore crystallization can be performed by the roll-to-roll method using a continuous roll of the substrate with a transparent electrode, which includes an amorphous transparent electrode layer. Moreover, the crystallization step can also be performed in the form of a continuous roll without unwinding a long sheet from the continuous roll of the substrate with a transparent electrode, which includes an amorphous transparent electrode layer.

### Effects of the Invention

According to the present invention, a substrate with a transparent electrode, which includes an amorphous transparent electrode layer having specific characteristics, is obtained. Although the amorphous transparent electrode layer is not heated at a high temperature, indium oxide that forms the transparent electrode layer is crystallized. Thus, the substrate with a transparent electrode according to the present invention can simplify a step of crystallizing a transparent electrode layer, and is therefore excellent in productivity. Further, the substrate with a transparent electrode according to the present invention can contribute to improvement in the response speed of a capacitance touch panel, improvement in in-plane uniformity of luminance in organic EL illumination, power saving of various optical devices, and the like, because the transparent electrode layer has a low resistance. Moreover, since it is not necessary to perform a heat treatment at a high temperature for crystallization, it can be expected that the dimensional change in a film base material in the manufacturing process of the substrate with a transparent electrode is small, thus making it easy to design a device.

### BRIEF DESCRIPTION OF THE DRAWINGS

FIG. 1 is a schematic sectional view of a substrate with a transparent electrode according to one embodiment.

FIG. 2 is a graph showing a time-dependent change in resistivity at room temperature in an Example and Comparative Example.

### MODE FOR CARRYING OUT THE INVENTION

[Configuration of Substrate with Transparent Electrode]

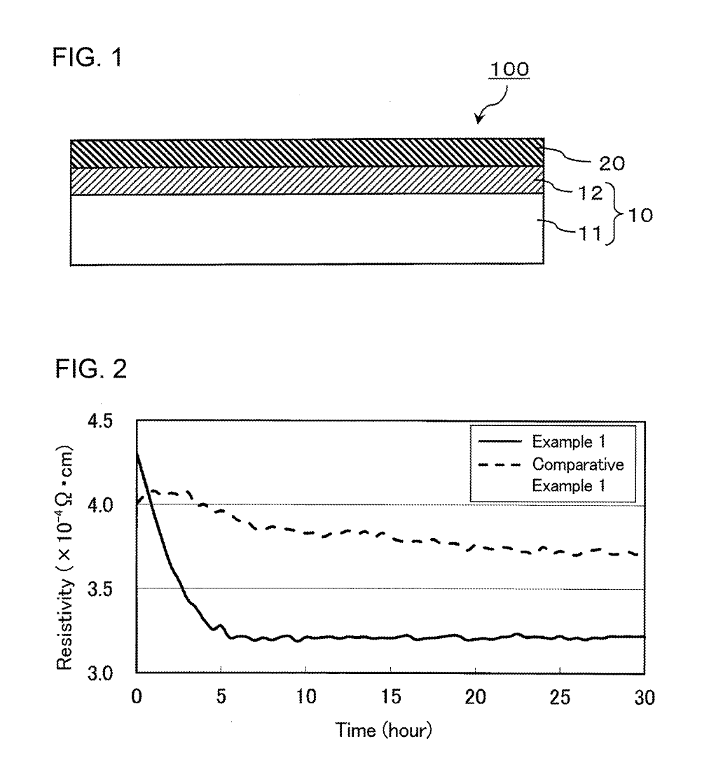

Preferred embodiments of the present invention will be described below with reference to the drawings. FIG. 1 shows a substrate 100 with a transparent electrode, which has a transparent electrode layer 20 on a transparent film base material 10.

A transparent film 11 that forms the transparent film base material 10 is preferably one that is colorless and transparent at least in a visible light region. A transparent dielectric material layer 12 containing an oxide as a main component is formed on the transparent film 11. The oxide that forms the transparent dielectric material layer 12 is preferably one that is colorless and transparent at least in a visible light region and has a resistivity of 10 Ω·cm or more. In this specification, “containing a substance as a main component” means that the content of the substance is 51% by weight or more, preferably 70% by weight or more, more preferably 90% by weight. Each layer may contain components other than the main component as long as the feature of the present invention is not impaired.

The substrate 100 with a transparent electrode according to the present invention includes a transparent electrode layer 20 on the transparent dielectric material layer 12 of the transparent film base material 10. For reducing resistance, preferably, the transparent electrode layer 20 is formed directly on the transparent dielectric material layer 12 of the transparent film base material 10.

Preferably, the transparent electrode layer 20 contains 87.5% by weight to 95.5% by weight of indium oxide. More preferably, the content of indium oxide is 90% by weight to 95% by weight. The transparent electrode layer contains a dope impurity for imparting conductivity with a carrier density provided in the film. The dope impurity is preferably tin oxide or zinc oxide. The transparent electrode layer includes indium tin oxide (ITO) when the dope impurity is tin oxide, and the transparent electrode layer includes indium zinc oxide (IZO) when the dope impurity is zinc oxide. The content of the dope impurity in the transparent electrode layer is preferably 4.5% by weight to 12.5% by weight, more preferably 5% by weight to 10% by weight. When the contents of indium oxide and the dope impurity are in the above-mentioned ranges, the transparent electrode layer is made to have a lower resistance, and moreover the amorphous transparent electrode layer can be converted into a crystalline film at room temperature or by low-temperature heating at 120° C. or lower.

For ensuring that the transparent electrode layer has a low resistance and a high transmittance, the thickness of the transparent electrode layer 20 is preferably 15 nm to 40 nm, more preferably 20 nm to 35 nm, further preferably 22 nm to 32 nm. Further, in the present invention, the thickness of the transparent electrode layer is preferably in the above-mentioned range for ensuring that the transparent electrode layer can be converted into a crystalline film by low-temperature heating or at room temperature.

In one embodiment of the present invention, the transparent electrode layer 20 is a crystalline transparent electrode layer having a crystallinity degree of 80% or more. The crystallinity degree of the crystalline transparent electrode layer is more preferably 90% or more. When the crystallinity degree is in the above-mentioned degree, absorption of light by the transparent electrode layer can be reduced, and a change in resistance value due to the environmental change or the like is suppressed. The crystallinity degree is determined from a ratio of an area of crystal grains in the observation visual field during microscopic observation.

Preferably, the crystalline transparent electrode layer has a resistivity of 3.5×10⁻⁴ Ω·cm or less. The surface resistance of the crystalline transparent electrode layer is preferably 150 Ω/sq or less, more preferably 130 Ω/sq or less. When the transparent electrode layer has a low resistance, it can contribute to improvement in the response speed of a capacitance touch panel, improvement in in-plane uniformity of luminance in organic EL illumination, power consumption saving of various kinds of optical devices, and the like.

The carrier density of the crystalline transparent electrode layer is preferably 4×10²⁰/cm³ to 9×10²⁰/cm³, more preferably 6×10²⁰/cm³ to 8×10²⁰/cm³. When the carrier density is in the above-mentioned range, the crystalline transparent electrode layer can be made to have a low resistance. In the present invention, by crystallizing an amorphous transparent electrode layer by low-temperature heating or at room temperature, the carrier density of the crystallized transparent electrode layer can be increased to be in the above-mentioned range even when the content of a dope impurity such as tin oxide or zinc oxide is relatively low.

The substrate 100 with a transparent electrode according to the present invention preferably has a heat shrinkage start temperature of 75° C. to 120° C., more preferably 78° C. to 110° C., further preferably 80° C. to 100° C. The heat shrinkage start temperature can be determined from the maximum value of a displacement amount when the temperature is elevated at a predetermined load and temperature elevation rate by thermomechanical analysis (TMA).

[Method for Manufacturing Substrate with Transparent Electrode]

Hereafter, preferred embodiments of the present invention will be described for the method for manufacturing a substrate with a transparent electrode. In the manufacturing method of the present invention, a transparent film base material 10 including a transparent dielectric material layer 12 on a transparent film 11 is used (base material providing step). A transparent electrode layer 20 is formed on the transparent dielectric material layer 12 of the transparent film base material 10 by the sputtering method (deposition step). Immediately after deposition, the transparent electrode layer 20 is amorphous with a crystallinity degree of less than 80%. The crystallinity degree immediately after deposition is preferably 70% or less, more preferably 50% or less, further preferably 30% or less, especially preferably 10% or less. As described later, a transparent electrode layer having a small crystallinity degree immediately after deposition tends to be crystallized by heating at a low temperature or for a short time.

After deposition of the transparent electrode layer, crystallization is performed (crystallization step). Generally, heating at a high temperature of about 150° C. is required for crystallizing an amorphous transparent electrode layer containing indium oxide as a main component. In contrast, the manufacturing method of the present invention is characterized in that crystallization is performed by low-temperature heating or at room temperature (or crystallization proceeds spontaneously).

(Base Material Providing Step)

The material of the transparent film 11 which forms the transparent film base material 10 is not particularly limited as long as it is colorless and transparent at least in a visible light region, and has heat resistance at a transparent electrode layer formation temperature. Examples of the material of the transparent film include polyester-based resins such as polyethylene terephthalate (PET), polybutylene terephthalate (PBT), and polyethylene naphthalate (PEN), a cycloolefin-based resin, a polycarbonate resin, a polyimide resin, and a cellulose-based resin. Among them, the polyester-based resin is preferable, and polyethylene terephthalate is especially preferably used.

The thickness of the transparent film 11 is not particularly limited, but is preferably 10 μm to 400 μm, more preferably 50 μm to 300 μm. When the thickness falls within the above-mentioned range, the transparent film 11 can have durability and proper flexibility, and therefore each transparent dielectric material layer and transparent electrode layer can be formed thereon with good productivity by a roll-to-roll method.

As the transparent film 11, one with mechanical characteristics such as Young's modulus and heat resistance that are improved by orienting molecules by biaxial stretching is preferably used. The heat shrinkage percentage of the transparent film base material 10 at 150° C. for 30 minutes before deposition of the transparent electrode layer is preferably 0.4% or more, more preferably 0.5% or more. When the heat shrinkage percentage varies depending on a direction (e.g., different between the MD direction and the TD direction), the heat shrinkage percentage in any one of the directions may be in the above-mentioned range. When the heat shrinkage percentage of the base material is in the above-mentioned range, the amorphous transparent electrode layer formed on the base material is likely a film that can be converted into a crystalline film by low-temperature heating or at room temperature.

Hereinafter, the “heat shrinkage percentage” in this specification refers to a shrinkage percentage when heating at 150° C. for 30 minutes unless otherwise specified. The heat shrinkage percentage is calculated from a distance (L₀) between two points before heating and a distance (L) between two points after heating in accordance with the following equation:

Heat shrinkage percentage(%)=100×(L₀−L)/L₀

Generally, a stretched film has a property of being heat-shrunk when heated because a strain resulting from stretching remains in the molecular chain. A biaxially stretched film (low-heat-shrinkage film), of which the heat shrinkage percentage is reduced to about 0.2% or less by releasing stress by adjustment of conditions for stretching or heating after stretching and of which the heat shrinkage start temperature is increased for reducing the above-mentioned heat shrinkage, is known. Use of such a low-heat-shrinkage film as a base material is also proposed from the viewpoint of inhibiting a failure resulting from heat shrinkage of the base material in the manufacturing process of the substrate with a transparent electrode.

In contrast, in the present invention, a biaxially stretched film, which is not subjected to the heat shrinkage reducing treatment described above and has a heat shrinkage percentage of 0.4% or more, is suitably used. In the present invention, deposition and crystallization of the transparent electrode layer is performed at a low temperature, so that even when a base material having a high heat shrinkage percentage is used, a significant change in dimension of the base material in the manufacturing process is inhibited. On the other hand, when the heat shrinkage percentage of the base material is extremely high, handling of the film in the deposition step and the subsequent manufacturing process of a touch panel may be difficult. Accordingly, the heat shrinkage percentage of the transparent film base 10 before deposition of the transparent electrode layer is preferably 1.5% or less, more preferably 1.2% or less.

The reason why the transparent electrode layer is easily crystallized when the base material has a heat shrinkage percentage of 0.4% or more is not clear, but this may be ascribed to perturbation given to the molecular structure of a conductive oxide in the amorphous transparent electrode by stress at a deposition interface with the base material during deposition of the transparent electrode layer.

The transparent film base material 10 before deposition of the transparent electrode layer preferably has a heat shrinkage start temperature of 75° C. to 120° C., more preferably 78° C. to 110° C. Generally, the heat shrinkage start temperature of a film subjected to a heat shrinkage reducing treatment exceeds 120° C., whereas a biaxially stretched film which is not subjected to a heat shrinkage reducing treatment has a heat shrinkage start temperature in the above-mentioned range.

As the oxide that forms the transparent dielectric material layer 12 formed on the transparent film 11, an oxide of at least one element selected from the group consisting of Si, Nb, Ta, Ti, Zn, Zr and Hf is suitably used. Among them, a dielectric material having a high bonding strength with oxygen, such as silicon oxide (SiO₂) or titanium oxide (TiO₂), is preferred, and silicon oxide is especially preferred.

The transparent dielectric material layer 12 can act as a gas barrier layer that suppresses volatilization of moisture and an organic substance from the transparent film 11 when the transparent electrode layer 20 is formed thereon, and a protective layer that reduces plasma damage on the transparent film, as well as a ground layer for film growth. Particularly, in the present invention, functioning of the dielectric material layer as an oxygen gas barrier layer is considered to contribute to formation of a transparent electrode layer capable of being crystallized by low-temperature heating or at room temperature. For ensuring that the transparent dielectric material layer has the above-mentioned functions, the thickness of the transparent dielectric material layer 12 is preferably 10 nm to 100 nm, more preferably 15 nm to 75 nm, further preferably 20 nm to 60 nm.

The transparent dielectric material layer 12 may include only one layer, or may include two or more layers. When the transparent dielectric material layer 12 includes two or more layers, by adjusting the thickness and refractive index of each layer, the transmittance and reflectivity of the substrate with a transparent electrode can be adjusted to enhance visibility of a display device. In a substrate with a transparent electrode for use in a capacitance touch panel, a part of the plane of the transparent electrode layer 20 is patterned by etching or the like. In this case, by adjusting the thickness and refractive index of the transparent dielectric material layer, a transmittance difference, a reflectivity difference, a color difference, and the like between an electrode-formed part where the electrode layer is not etched and remains and an electrode-non-formed part where the electrode layer is removed by etching can be reduced to inhibit visibility of an electrode pattern.

The transparent film base material 10 may have a functional layer (not shown) such as a hard coat layer on one or both of the surfaces of a transparent film 11 in addition to the above transparent dielectric material layer 12. For the transparent film base material to have proper durability and flexibility, the thickness of the hard coat layer is preferably 3 to 10 μm, more preferably 3 to 8 μm, further preferably 5 to 8 μm. The material of the hard coat layer is not particularly limited. Urethane-based resin, acrylic resin, silicone-based resin or the like being applied and cured can be appropriately used. When a functional layer such as a hard coat layer is formed on a surface of the transparent film 11, where the transparent electrode layer 20 is formed, the functional layer is preferably formed between the transparent film 11 and the transparent dielectric material layer 12.

The arithmetic mean roughness Ra of a surface of the transparent film base material 10, where the transparent electrode layer is formed, i.e., the surface of the transparent dielectric material layer 12, is preferably 0.4 nm to 5 nm, more preferably 0.5 nm to 3 nm. The state of formation (deposition) of the transparent electrode layer 20 is easily affected by the shape of the surface of the dielectric material layer which provides a deposition interface, so that by smoothening the surface to reduce Ra, an amorphous film capable of being crystallized even at a low temperature is easily obtained. The shape of the surface of the transparent dielectric material layer 12 is also affected by the shape of the surface of the transparent film 11, and therefore Ra is generally 0.4 nm or more. The arithmetic mean roughness Ra is calculated in accordance with JIS B0601: 2001 (ISO 1302: 2002) on the basis of a surface shape (roughness curve) measured by a non-contact method using a scanning probe microscope.

The method for formation of the transparent dielectric material layer 12 on the transparent film 11 is not particularly limited as long as a uniform thin film is formed. Examples of the film formation method include: dry coating methods such as PVD methods (such as a sputtering method and a vapor deposition method) and various kinds of CVD methods; and wet coating methods such as a spin coating method, a roll coating method, a spray coating method and a dipping coating method. Among the film formation methods described above, dry coating methods are preferred because a thin film at a nanometer level is easily formed. Particularly, when it is required to control the layer thickness in the order of several nanometers for adjusting optical characteristics and the like, the sputtering method is preferred. The surface of the transparent film 11 may be subjected to a surface treatment such as a corona discharge treatment or a plasma treatment prior to formation of the transparent dielectric material layer for the purpose of enhancing adhesion between the transparent film 11 and the transparent dielectric material layer 12.

(Deposition Step)

A transparent electrode layer 20 is formed on the transparent dielectric material layer 12 of the transparent film base material 10 by the sputtering method. The transparent electrode layer 20 is an amorphous film immediately after deposition. For reducing the resistance of the transparent electrode layer and crystallizing the amorphous film by low-temperature heating or at room temperature, the transparent electrode layer 20 is preferably formed directly on the transparent dielectric material layer 12 of the transparent film base material 10.

As a sputtering power source, a DC, RF, or MF power source or the like can be used. A metal, a metal oxide, or the like is used as a target to be used for sputtering deposition. Particularly, an oxide target containing indium oxide and tin oxide or containing indium oxide and zinc oxide is suitably used. The oxide target is preferably one containing indium oxide in an amount of 87.5% by weight to 95.5% by weight, more preferably 90% by weight to 95% by weight. The oxide target is preferably one containing, in addition to indium oxide, tin oxide or zinc oxide in an amount of 4.5% by weight to 12.5% by weight, more preferably 5% by weight to 10% by weight.

Sputtering deposition is performed while a carrier gas including an inert gas such as argon or nitrogen and an oxygen gas is introduced into a deposition chamber. As the gas to be introduced, a mixed gas of argon and oxygen is preferred. The mixed gas preferably contains oxygen in an amount of 0.4 to 2.0% by volume, more preferably in an amount of 0.7 to 1.5% by volume. By supplying the above-mentioned volume of oxygen, the transparency and electrical conductivity of the transparent electrode layer can be improved. The mixed gas may contain other gases as long as the feature of the present invention is not impaired. The pressure (total pressure) in the deposition chamber is preferably 0.1 Pa to 1.0 Pa, more preferably 0.25 Pa to 0.8 Pa.

In the present invention, the oxygen partial pressure in the deposition chamber during deposition is preferably 1×10⁻³ Pa to 5×10⁻³ Pa, more preferably 2.3×10⁻³ Pa to 4.3×10⁻³ Pa. The oxygen partial pressure range is below the value of an oxygen partial pressure in general sputtering deposition. That is, in the present invention, deposition is performed with a small oxygen supply amount. Therefore, it is considered that significant oxygen vacancy occurs in the amorphous film after deposition.

The temperature of the substrate during deposition may be in a range where the transparent film base material has heat resistance, and a temperature of 60° C. or lower is preferred. The temperature of the substrate is more preferably −20° C. to 40° C., further preferably −10° C. to 20° C. When the temperature of the substrate is 60° C. or lower, volatilization or the like of moisture and an organic substance (e.g., oligomer component) from the transparent film base material is less likely to occur, indium oxide is easily crystallized, and an increase in resistivity of the crystalline transparent electrode layer after the amorphous film is crystallized can be suppressed. When the temperature of the substrate is in the above-mentioned range, a decrease in transmittance of the transparent electrode layer and embrittlement of the transparent film base material are suppressed, and the film base material does not undergo a significant dimensional change in the deposition step.

Preferably, the heat shrinkage percentage and heat shrinkage start temperature of the substrate with an amorphous transparent electrode layer after deposition of the transparent electrode layer is approximately equivalent to the heat shrinkage percentage and heat shrinkage start temperature of the transparent film base material before deposition of the transparent electrode layer because the film base material does not undergo a significant dimensional change before and after deposition of the transparent electrode layer. That is, the substrate with an amorphous transparent electrode layer preferably has a heat shrinkage percentage of 0.4% or more. The heat shrinkage percentage of the substrate with an amorphous transparent electrode layer is preferably 1.5% or less, more preferably 1.2% or less. Further, the substrate with an amorphous transparent electrode layer preferably has a heat shrinkage start temperature of 75° C. to 120° C., more preferably 78° C. to 110° C., further preferably 80° C. to 100° C.

Preferably, the transparent electrode layer is deposited with a thickness of 15 nm to 40 nm. The deposition thickness is more preferably 20 nm to 35 nm, further preferably 22 nm to 32 nm. When the deposition thickness is in the above-mentioned range, the transparent electrode layer can be converted into a crystalline film by low-temperature heating or at room temperature.

In the present invention, preferably, deposition is performed by the roll-to-roll method using a roll-to-roll sputtering apparatus. When deposition is performed by the roll-to-roll method, a roll-shaped body (continuous roll) of a long sheet of the transparent film base material provided with a formed amorphous transparent electrode layer is obtained. When the transparent dielectric material layer 12 is formed on the transparent film 11 using a roll-to-roll sputtering apparatus, the transparent dielectric material layer 12 and the transparent electrode layer 20 may be successively deposited.

Generally, heating at a high temperature for a long time is required for crystallizing an amorphous transparent electrode layer, and therefore even when the transparent electrode layer is deposited by the roll-to-roll method, subsequent crystallization is performed with the film cut into a sheet having a predetermined size. In contrast, in the present invention, crystallization is performed by low-temperature heating or at room temperature, and therefore crystallization can be performed in the form of a roll without cutting the film from a continuous roll of a long sheet, so that productivity of the substrate with a transparent electrode can be enhanced.

For ensuring that crystallization can be performed by low-temperature heating or at room temperature as described above, the amorphous transparent electrode layer formed on the transparent film base material preferably has an activation energy ΔE of 1.3 eV or less, more preferably 1.1 eV or less, further preferably 1.0 eV or less when crystallized. The activation energy ΔE is preferably as low as possible, and is especially preferably 0.9 eV or less, further preferably 0.8 eV or less, further more preferably 0.7 eV or less, most preferably 0.6 eV or less. As shown in examples described later, the activation energy tends to increase when the oxygen partial pressure during sputtering deposition is decreased. The activation energy can be calculated using an Arrhenius plot from a dependency of a reaction rate constant k on temperature when the amorphous transparent electrode layer is crystallized. Details of the method for calculating the activation energy will be described later.

(Crystallization Step)

The base material provided with an amorphous transparent electrode layer is subjected to a crystallization step. In the manufacturing method of the present invention, preferably, the base material is not heated to 120° C. or higher in the crystallization step. That is, preferably, the crystallization step is performed at ambient temperature without heating the base material, or performed at a temperature lower than 120° C. when the base material is heated. The heating temperature in the crystallization step is preferably lower than 100° C., more preferably lower than 80° C., further preferably lower than 60° C. Further, the heating temperature is preferably lower than a heat shrinkage start temperature Tₛ of the base material after deposition of the transparent electrode layer, more preferably lower than Tₛ−10° C., further preferably lower than Tₛ−20° C. Most preferably, crystallization occurs spontaneously at ambient temperature and ambient pressure without performing heating.

The crystallization time is not particularly limited, and is about 1 to 10 days in the case of crystallization at ambient temperature. When heating is performed, it is preferable that crystallization is performed in a shorter time. In the present invention, crystallization may be performed at a low temperature as described above because the transparent electrode layer is deposited under the above-mentioned specific conditions. Preferably, crystallization is performed under an atmosphere containing oxygen, for example, in the air, for taking sufficient oxygen into the film to shorten the crystallization time. Although crystallization proceeds in a vacuum or under an inert gas atmosphere, it tends to take a longer time for crystallization under a low-oxygen-concentration atmosphere as compared to an oxygen atmosphere.

When the continuous roll of a long sheet is subjected to the crystallization step, crystallization may be performed in the form of the continuous roll, or crystallization may be performed while the film is conveyed in a roll-to-roll manner, or crystallization may be performed with the film cut into a predetermined size. In the present invention, preferably, crystallization is performed in the form of a continuous roll or in a roll-to-roll manner without cutting the film because crystallization is performed by low temperature heating or at ambient temperature.

When crystallization is performed in the form of a continuous roll, the base material after formation of the transparent electrode layer may be placed directly in an ambient temperature and ambient pressure environment, or aged (left standing) in a heating chamber or the like. When crystallization is performed in a roll-to-roll manner, the base material is introduced into a heating furnace to be heated while being conveyed, and is then wound into a roll shape again. Even when crystallization is performed at room temperature, the roll-to-roll method may be employed for the purpose of bringing the transparent electrode layer into contact with oxygen to promote crystallization, and the like.

The substrate with a transparent electrode after the transparent electrode layer is crystallized as described above is not heated at a high temperature of 120° C. or higher in the manufacturing process, and therefore there is no significant difference in thermal history between the base material before the transparent electrode layer is deposited and the base material after the transparent electrode layer is deposited and crystallized, so that a change in heat shrinkage start temperature and a change in heating shrinkage percentage are small. Accordingly, the substrate with a transparent electrode according to the present invention can have a heat shrinkage start temperature of 75° C. to 120° C. When crystallization is performed at a low temperature, the carrier density tends to increase due to crystallization, and a crystalline transparent electrode layer having a carrier density of 4×10²⁰/cm³ or more and a resistivity of 3.5×10⁻⁴ Ω·cm or less is obtained.

[Estimated Principle]

It is considered that in the present invention, crystallization at room temperature or by low-temperature heating is possible due to the unique state of the amorphous film after deposition. Particularly, it is considered that in the present invention, significant oxygen vacancy occurs in the amorphous film because the oxygen partial pressure during deposition is low. The substrate with an electrode according to the present invention is thought to have significant oxygen vacancy because the carrier density in the transparent electrode layer is high.

It is thought that in the amorphous state with significant oxygen vacancy, the molecular structure is unstable, and therefore potential energy is high, so that the activation energy ΔE for crystallization is decreased, thereby contributing to crystallization at a low temperature. According to the Arrhenius equation, the reaction rate constant k is proportional to exp(−ΔE/RT), and therefore when the activation energy ΔE is decreased, crystallization proceeds even though the temperature T is low.

Many attempts have been made heretofore to crystallize an amorphous metal oxide by heating at a low temperature or for a short time, but most of them are intended to increase the crystallinity degree (crystal fraction) of the amorphous film during deposition or generate a crystal nucleus to thereby promote subsequent crystallization by heating. In contrast, the crystal having significant oxygen vacancy in the film has an unstable structure, and therefore the amorphous transparent electrode layer immediately after deposition in the present invention is considered to be substantially completely amorphous. That the film can be easily crystallized by low-temperature heating or at room temperature although the crystallinity degree immediately after deposition is low may be the finding that has been previously unknown.

Studies by the present inventors show that even though the conditions for deposition of the amorphous film are the same, crystallization does not occur at a low temperature when the transparent film base material has no transparent dielectric material layer. Thus, the state of a deposition interface of the transparent electrode layer may also be a factor to enable crystallization at a low temperature. For example, a dielectric material layer having a high bonding strength with oxygen, such as that of silicon oxide, may act as a gas barrier layer that inhibits the base material from being affected by plasma damage during deposition and inhibits an oxygen gas generated from the base material by plasma damage from being taken into the film. Therefore, it is also considered that oxygen vacancy in the amorphous film is increased due to the presence of the transparent dielectric material layer.

Studies by the present inventors show that even though the conditions for deposition of the amorphous film are the same, crystallization does not occur at a low temperature when the thickness of the transparent electrode layer is less than 15 nm or more than 40 nm. Generally, thin films having a thickness of several nm to several hundred nm are known to vary in characteristics depending on a thickness as those having a smaller thickness (in the initial stage of deposition) are strongly affected by the base material, and those having a larger thickness have bulk-like characteristics. It is also considered that in the manufacturing method of the present invention, the transparent electrode layer having a thickness in a range from 15 to 40 nm has a unique amorphous state or transition state in which the layer is crystallized from the amorphous state, so that the activation energy ΔE is decreased to enable crystallization at room temperature.

Studies by the present inventors show that crystallization is less likely to occur at a low temperature even when a biaxially stretched film subjected to a heat shrinkage treatment is used as a transparent film to be subjected to the deposition step. Thus, stress at a deposition interface with the base material during deposition of the transparent electrode layer may also give perturbation to the amorphous state or the transition state in which the layer is crystallized from the amorphous state.

[Use of Substrate with Transparent Electrode]

The substrate with a transparent electrode according to the present invention can be used as a transparent electrode of a display, a light emitting element, a photoelectric conversion element and the like, and is suitably used as a transparent electrode for a touch panel. Particularly, the substrate with a transparent electrode is suitably used for a capacitance touch panel because the transparent electrode layer has a low resistance.

In formation of a touch panel, an electroconductive ink or paste is applied onto the substrate with a transparent electrode, and heat treatment is performed to form a collecting electrode as a wiring for routing circuit. The heat treatment method is not particularly limited, and examples thereof include a method of heating using an oven, an IR heater, or the like. The temperature/time for the heat treatment is appropriately set in consideration of a temperature/time that allows the electroconductive paste to be attached to the transparent electrode. Examples include a heat treatment at 120 to 150° C. for 30 to 60 minutes for heating by the oven, and a heat treatment at 150° C. for 5 minutes for heating by the IR heater. The method for formation of a wiring for routing circuit is not limited to the above-mentioned method, and the wiring may be formed by a dry coating method. When the wiring for routing circuit is formed by photolithography, the wiring can be made thinner.

### EXAMPLES

The present invention will be described more specifically below by way of examples, but the present invention is not limited to these examples.

A value determined by transmission electron microscope (TEM) observation of a cross section of a substrate with a transparent electrode was used for the thickness of each of the transparent dielectric material layers and the transparent electrode layer. The surface resistance of the transparent electrode layer was measured by four-point probe pressure contact measurement using a low resistivity meter Loresta GP (MCP-T710 manufactured by Mitsubishi Chemical Corporation). The resistivity of the transparent electrode layer was calculated from a product of the value of the above-mentioned surface resistance and the thickness.

The carrier density of the transparent electrode layer was measured by the van der Pauw method. A sample was cut into a 1 cm square, and metal indium was fused to four corners thereof as an electrode. A hole mobility was measured based on a potential difference when allowing a current of 1 mA to pass in the diagonal direction of the substrate with a magnetic force of 3,500 gausses, and a carrier density was calculated.

The crystallinity degree of the transparent electrode layer was determined from an area ratio of crystal grains in the visual field based on a plane observation photograph of the transparent electrode layer taken with a scanning transmission electron microscope (STEM).

The heat shrinkage start temperature was measured by thermomechanical analysis. A sample cut into a width of 5 mm was subjected to thermomechanical analysis (TMA) under conditions of a load of 0.1 g/mm, an initial length of 20 mm, and a temperature elevation rate of 10° C./minute, and the temperature at which the displacement was a maximum was defined as a heat shrinkage start temperature. The heat shrinkage percentage was determined by punching the sample at two points at an interval of 10 mm and measuring a distance L₀ between two points before heating at 150° C. for 30 minutes and a distance L between two points after the heating with a three-dimensional distance meter.

<Calculation of Activation Energy>

The activation energy ΔE at the time of crystallizing the amorphous transparent electrode layer was calculated from a dependency of a reaction rate constant k on temperature at the time of heating the substrate with an amorphous transparent electrode layer at a predetermined temperature to be crystallized. For each heating temperature, the heating time was plotted on the abscissa axis and the surface resistance of the transparent electrode layer was plotted on the ordinate axis, and a time t was determined at which the surface resistance value reached an average of the initial value (at the start of measurement) and the final value (state in which crystallization was completed to achieve a crystallinity degree of almost 100%). A reaction rate constant k was calculated at each heating temperature by substituting a reaction ratio of 0.5 into the equation: reaction ratio=1−exp(kt) with the reaction ratio considered to be 50% at the time t.

From the reaction rate constant k and heating temperature at each of heating temperatures of 130° C., 140° C., and 150° C., Arrhenius plotting (abscissa axis: 1/RT and ordinate axis: logₑ(1/k)) was performed, and the slope of the line was defined as an activation energy ΔE. Here, R is a gas constant, T is an absolute temperature, and e is a base of natural logarithm.

### Example 1

### Preparation of Transparent Film Base Material

As a transparent film, a 188 μm-thick, biaxially stretched PET film provided with a hard coat layer made of a urethane-based resin formed on both surfaces thereof (heat shrinkage start temperature: 85° C.; heat shrinkage percentage during heating at 150° C. for 30 minutes: 0.6%) was used. A 40 nm-thick transparent dielectric material electrode layer made of silicon oxide (SiO₂) was formed on one of the surfaces of the PET film by the sputtering method.

(Deposition of Amorphous Transparent Electrode Layer)

Using indium tin oxide (content of tin oxide: 5% by weight) as a target, sputtering was performed under conditions of an oxygen partial pressure of 5×10⁻³ Pa, a deposition chamber internal pressure of 0.5 Pa, a substrate temperature of 0° C., and a power density of 4 W/cm² while a mixed gas of oxygen and argon was introduced into the chamber. The thickness of the obtained ITO layer was 25 nm.

The substrate with a transparent electrode had a transparent electrode layer having a resistivity of 4.0×10⁻⁴ Ω·cm and a carrier density of 3.0×10²⁰/cm³ immediately after deposition of an ITO film with almost no crystal grain observed by microscopic observation (crystallinity degree: 0%).

(Crystallization)

The substrate with a transparent electrode had a resistivity of 3.2×10⁻⁴ Ω·cm, a surface resistance of 128 Ω/sq, and a carrier density of 6.3×10²⁰/cm³ after being left standing at room temperature (25° C.) for 24 hours, and was confirmed to be almost completely crystallized by microscopic observation (crystallinity degree: 100%). The substrate with a transparent electrode had a heat-shrinkage start temperature of 85° C. and a heat-shrinkage percentage of 0.6%, each of which was unchanged from that before deposition of the transparent electrode layer.

### Examples 2 to 5 and Comparative Examples 1 and 2

Deposition and crystallization were performed in the same manner as in Example 1 except that the type of a target (tin oxide content) and the oxygen partial pressure (introduction gas amount ratio) during deposition of the amorphous transparent electrode layer and the crystallization conditions (temperature and time) were changed as shown in Table 1.

Conditions and measurement results for Examples and Comparative Examples described above are listed in Table 1. A time-dependent change in resistivity at ambient temperature and ambient pressure from immediately after deposition in each of Example 1 and Comparative Example 1 is shown in FIG. 2.

TABLE 1

| | | | | | | | | | Crystalline | |
|---|---|---|---|---|---|---|---|---|---|---|
| | Amorphous transparent electrode layer | | | | | | | | transparent | |
| | deposition | | | | | | | | electrode | |
| | condition | | | | characteristics | | | | layer | |
| | | oxygen | | | immediately after deposition | | | | crystallization | |
| | SnO₂ | partial | O₂/Ar | | crystallinity | | carrier | | condition | |
| | content | pressure | introduction | thickness | degree | resistivity | density | ΔE | temperature | time |
| | (wt %) | (mPa) | ratio | (nm) | (%) | (×10⁻⁴ Ω · cm) | (×10²⁰ cm⁻³) | (eV) | (° C.) | (hour) |
| Example 1 | 5 | 5 | 10/1000 | 25 | 0 | 4.0 | 3.0 | 1.01 | 25 | 24 |
| Example 2 | 5 | 2 | 4/1000 | 25 | 0 | 4.0 | 3.4 | 0.48 | 25 | 24 |
| Example 3 | 5 | 5 | 10/1000 | 32 | 0 | 3.6 | 4.2 | 0.79 | 25 | 18 |
| Example 4 | 10 | 5 | 10/1000 | 25 | 0 | 3.4 | 5.2 | 0.80 | 25 | 36 |
| Example 5 | 10 | 2 | 4/1000 | 25 | 0 | 3.3 | 6.2 | 0.55 | 25 | 24 |
| Comparative | 5 | 12 | 24/1000 | 25 | <15 | 4.2 | 3.0 | 1.46 | 25 | 24 |
| Example 1 | | | | | | | | | | |
| Comparative | 5 | 12 | 24/1000 | 25 | <15 | 4.1 | 3.0 | 1.40 | 150 | 0.5 |
| Example 2 | | | | | | | | | | |

| | Crystalline transparent electrode layer | | | | | |
|---|---|---|---|---|---|---|
| | characteristics | | | | | |
| | after crystallization | | | | | |
| | | | | | | heat- |
| | | | | | heat- | shrinkage |
| | | carrier | surface | crystallinity | shrinkage | start |
| | resistivity | density | resistance | degree | percentage | temperature |
| | (×10⁻⁴ Ω · cm) | (×10²⁰ cm⁻³) | (Ω/sq) | (%) | (%) | (° C.) |
| Example 1 | 3.2 | 6.3 | 128 | ≈100 | 0.6 | 85 |
| Example 2 | 2.4 | 7.2 | 96 | ≈100 | 0.6 | 85 |
| Example 3 | 3.0 | 7.0 | 120 | ≈100 | 0.6 | 85 |
| Example 4 | 3.0 | 5.8 | 120 | ≈100 | 0.6 | 85 |
| Example 5 | 2.9 | 6.4 | 116 | ≈100 | 0.6 | 85 |
| Comparative | 3.8 | 3.2 | 154 | <20 | 0.6 | 85 |
| Example 1 | | | | | | |
| Comparative | 3.3 | 5.0 | 132 | ≈100 | 0.1 | 155 |
| Example 2 | | | | | | |

In Comparative Example 1 where the oxygen partial pressure was increased to 1.2×10⁻² Pa during deposition of the transparent electrode layer, it was confirmed by microscopic observation that crystal grains were locally present immediately after deposition (crystallinity degree<15%). In Comparative Example 1, the crystallinity degree was slightly increased after the sample was left standing at room temperature for 24 hours after deposition (crystallinity degree<20%), but complete crystallization was not achieved, and the resistivity was not sufficiently decreased as compared to Example 1. Referring to FIG. 2, it is considered that even in Comparative Example 1, crystallization proceeds slowly at ambient temperature, and the resistivity is decreased with time. However, crystallization at ambient temperature may be impracticable because crystallization at ambient temperature requires a time period of approximately several months to one year in consideration of the reaction rate.

In Comparative Example 2 where crystallization was performed by heating at 150° C. for 30 minutes after deposition was performed under the same conditions as those in Comparative Example 1, almost complete crystallization was achieved after the heating. In Comparative Example 2, the heat shrinkage start temperature was increased, so that the heat shrinkage percentage was decreased, as compared to those before heating. This shows that in Comparative example 2, the base material undergoes a dimensional change (heat shrinkage) due to heating during crystallization. In contrast, in each Example, the heat shrinkage start temperature was not changed before and after crystallization because heating was not performed at the time of crystallization.

It is apparent that in each Example where deposition was performed at a lower oxygen partial pressure as compared to Comparative Examples 1 and 2, the activation energy ΔE in crystallization of an amorphous film is low, so that crystallization is possible even at ambient temperature.

In Example 3 where the thickness of the transparent electrode layer was larger as compared to Example 1, a transparent electrode layer having an increased carrier density and a lower resistivity was obtained. It is considered that by increasing the deposition thickness, a change occurs in the amorphous state immediately after deposition due to stabilization of film growth and influence of plasma radiant heat during deposition. For example, it is considered that when the deposition thickness is large, a film which is amorphous but has a short-distance order is obtained, so that crystallization readily occurs.

It is apparent that in Examples 4 and 5 where the content of tin oxide is higher as compared to Examples 1 and 2, crystallization is performed at ambient temperature after deposition, so that a crystalline transparent electrode layer having a low resistance is obtained.

Comparison between Example 1 and Example 2 shows that when the oxygen partial pressure during deposition is decreased, the carrier density is increased, and the resistivity after crystallization at room temperature is decreased. Comparison between Example 4 and Example 5 shows a tendency similar to that described above. Comparison between Example 1 and Example 2 and comparison between Example 4 and Example 5 show that when the oxygen partial pressure during deposition is decreased, the activation energy ΔE at the time of crystallization is decreased, so that crystallization readily proceeds. From the results described above, it is thought that since deposition is performed at a low oxygen partial pressure, oxygen vacancy in the film is increased, so that potential energy in the amorphous state immediately after deposition is high, and therefore the activation energy ΔE for crystallization is decreased, thereby contributing to crystallization at a low temperature.

### DESCRIPTION OF REFERENCE CHARACTERS

10 transparent film base material
11 transparent film
12 transparent dielectric material layer
20 transparent electrode layer
100 substrate with transparent electrode

1-15. (canceled)

16. A substrate with a transparent electrode, comprising: a transparent film base material; and a crystalline transparent electrode layer on at least one surface of the transparent film base material, wherein
the transparent film base material has a transparent dielectric material layer containing an oxide as a main component on a surface at the crystalline transparent electrode layer side,
the crystalline transparent electrode layer has a resistivity of 3.5×10⁻⁴ Ω·cm or less, a thickness of 15 nm to 40 nm, an indium oxide content of 87.5% to 95.5%, a carrier density of 4×10²⁰/cm³ to 9×10²⁰/cm³, and a crystallinity degree of 80% or more, and
a heat shrinkage start temperature as measured by thermomechanical analysis is 75° C. to 120° C.

17. The substrate with the transparent electrode according to claim 16, wherein the transparent electrode layer further contains tin oxide or zinc oxide.

18. The substrate with the transparent electrode according to claim 16, wherein the transparent dielectric material layer contains silicon oxide as a main component.

19. The substrate with the transparent electrode according to claim 16, wherein a long sheet of the substrate with a transparent electrode is wound in the form of a roll.

20. The substrate with the transparent electrode according to claim 16, wherein a heat shrinkage percentage is 0.4% or more at 150° C. for 30 minutes.

21. A substrate with the transparent electrode, comprising: a transparent film base material; and an amorphous transparent electrode layer on at least one surface of the transparent film base material, wherein
the transparent film base material has a transparent dielectric material layer containing an oxide as a main component on a surface at an amorphous transparent electrode layer side,
the amorphous transparent electrode layer has a thickness of 15 nm to 40 nm, an indium oxide content of 87.5% to 95.5%, and a crystallinity degree of less than 80%,
an activation energy at a time of crystallizing the amorphous transparent electrode layer is 1.3 eV or less, and
a heat shrinkage start temperature as measured by thermomechanical analysis is 75° C. to 120° C.

22. The substrate with the transparent electrode according to claim 21, wherein the transparent electrode layer further contains tin oxide or zinc oxide.

23. The substrate with the transparent electrode according to claim 21, wherein the transparent dielectric material layer contains silicon oxide as a main component.

24. The substrate with the transparent electrode according to claim 21, wherein a long sheet of the substrate with a transparent electrode is wound in the form of a roll.

25. The substrate with the transparent electrode according to claim 21, wherein a heat shrinkage percentage is 0.4% or more at 150° C. for 30 minutes.

26. A method for manufacturing a substrate with a transparent electrode, which comprises a transparent film base material and a crystalline transparent electrode layer on at least one surface of the transparent film base material, the transparent electrode layer having a resistivity of 3.5×10⁻⁴ Ω·cm or less and a crystallinity degree of 80% or more, the method comprising:
a base material providing step of providing a transparent film base material;
a deposition step of forming an amorphous transparent electrode layer having a thickness of 15 nm to 40 nm and an indium oxide content of 87.5% to 95.5% on a transparent dielectric material layer of the transparent film base material by a sputtering method; and
a crystallization step of crystallizing the amorphous transparent electrode layer to obtain a crystalline transparent electrode layer, wherein
in the deposition step, the deposition is performed at an oxygen partial pressure of 1×10⁻³ Pa to 5×10⁻³ Pa in a deposition chamber while a carrier gas including an inert gas and an oxygen gas is introduced into the chamber, and
in the crystallization step, the transparent film base material and the transparent electrode layer are not heated to 120° C. or higher.

27. The method for manufacturing the substrate with the transparent electrode according to claim 26, wherein
in the deposition step, the deposition is performed with a roll-to-roll sputtering apparatus to obtain a continuous roll of a long sheet of the transparent film base material provided with the amorphous transparent electrode layer, and
the substrate with the transparent electrode is a continuous roll with a long sheet wound in a roll shape.

28. The method for manufacturing the substrate with the transparent electrode according to claim 27, wherein the crystallization step is performed in the form of the continuous roll without unwinding the long sheet from the continuous roll.

29. The method for manufacturing the substrate with the transparent electrode according to claim 26, wherein the crystallization step is performed at ambient temperature and ambient pressure.

30. The method for manufacturing the substrate with the transparent electrode according to claim 26, wherein a temperature of the substrate in the deposition step is 60° C. or lower.

31. The method for manufacturing the substrate with the transparent electrode according to claim 26, wherein the transparent film base material before being subjected to the deposition step has a heat shrinkage start temperature of 75° C. to 120° C. as measured by thermomechanical analysis.

32. The method for manufacturing the substrate with the transparent electrode according to claim 26, wherein the transparent film base material before being subjected to the deposition step has a heat shrinkage percentage of 0.4% or more in at least one of directions during heating at 150° C. for 30 minutes.

33. The method for manufacturing the substrate with the transparent electrode according to claim 26, wherein the transparent electrode layer further contains tin oxide or zinc oxide.

34. The method for manufacturing the substrate with the transparent electrode according to claim 26, wherein the transparent dielectric material layer contains silicon oxide as a main component.
